(19) United States
(12) Patent Application Publication
(10) Pub. No.: US 2002/0130720 A1
(43) Pub. Date: Sep. 19, 2002

(54) Distributed amplifier with transistors in a cascode configuration and negative feedback

(75) Inventors: Anthony M. Pavio, Paradise Valley, AZ (US); Lei Zhao, Chandler, AZ (US)

Correspondence Address: MOTOROLA, INC., CORPORATE LAW DEPARTMENT - #56-238, 3102 NORTH 56TH STREET, PHOENIX, AZ, 85018, US

(73) Assignee: Motorola, Inc.

(21) Appl. No.: 09/809,373

(22) Filed: Mar. 15, 2001

(51) Int. Cl. H03F 3/60; H03F 3/68; H03F 1/22

(52) U.S. Cl. 330/286; 330/295; 330/311

(57) ABSTRACT

A distributed amplifier (40) is provided that comprises an input transmission line (48) and an output transmission line (50). The distributed amplifier (40) also comprises a first distributed amplifier cell (42) and second distributed amplifier cell (44) connected to the input transmission line (48) and the output transmission line (50). The first distributed amplifier cell (42) and second distributed amplifier cell (44) has a first transistor (52) and a second transistor (54) in a first cascode configuration between the input transmission line (48) and the output transmission line (50) and the first transistor (52) is configured with a first feedback loop (78) and the second transistor (54) is configured with a second feedback loop (80).

### FIELD OF THE INVENTION

The present invention generally relates to amplifiers, and more particularly to a distributed amplifier having transistors in a cascode configuration and negative feedback.

### BACKGROUND OF THE INVENTION

Distributed amplifiers and mixers have been used extensively for many years in a variety of broadband system applications such as microwave receivers, wide-band transmitter exciters and low noise oscilloscope preamplifiers. Distributed amplifiers conventionally employ either a single transistor or multiple transistors in a cascode configuration for the amplifier cells within the distributed transmission line networks. The conventional configuration of multiple transistors in a cascode configuration generally exhibits the desired increase in gain and also provides gain controllability.

Referring to FIG. 1, a distributed amplifier 10 is illustrated according to the prior art. The distributed amplifier 10 is shown with multiple cells (12,14,16). Each of the cells (12,14,16) includes a first field effect transistor (FET) 18 in a cascode configuration with a second FET 20. The cascode configuration of the first FET 18 and second FET 20 of each of the cells (12,14,16) has the first FET 18 in a common source arrangement and second FET 20 in a common gate arrangement and the first FET 18 is configured to drive the second FET 20. The drain terminals 22 of the second FET 20 of each of the cells (12,14,16) are coupled with output-line inductances 24, which are connected to an output-line ground 26 with an output-line termination resistance 28. The gate terminals 30 of the first FET 18 of each of the cells (12,14,16) are coupled with input-line inductances 32 that are connected to an input-line ground 34 with an input-line termination resistance 36.

The cascode configuration of the first FET 18 and the second FET 20 for each of the cells (12,14,16) forming the distributed amplifier 10 exhibits an increase in gain. However, the cascode configuration of the first FET 18 and second FET 20 for each of the cells (12,14,16) generally fails to improve distortion. In addition, the cascode configuration of the first FET 18 and second FET 20 for each of the cells (12,14,16) does not effectively utilize the gain at frequencies from about two to twenty Giga-Hertz (GHz).

Distributed amplifiers of the prior art, such as the distributed amplifier 10 shown in FIG. 1, that are designed to operate from about two to twenty Giga-Hertz (GHz) (i.e., microwave amplifiers) have been fabricated on gallium arsenide (GaAs) substrates. These microwave amplifiers that are fabricated on GaAs substrates have circuit elements with relatively small values, which require minimal space on the GaAs substrate (e.g., inductors of one nH to two nH typically require an area of fifteen microns by fifteen microns). However, if the distributed amplifier is designed for frequencies below about three GHz, numerous circuit elements are used with values that require a larger space on the GaAs substrate than the circuit elements used for distributed amplifiers designed for frequencies greater than about ten GHz (e.g. an output-line inductances 24 of ten nH would generally require an area of sixty microns by sixty microns.) Therefore, the distributed amplifiers that are designed for frequencies below about ten GHz on GaAs substrates tend to utilize an undesirable amount of semiconductor material that reduces the cost effectiveness of such a device.

In view of the foregoing, it should be appreciated that it would be desirable to increase the cost effectiveness of a distributed amplifier and more preferably to increase the cost effectiveness of a distributed amplifier that is designed for frequencies below about twenty GHz, more preferably below about ten GHz, even more preferably below about five GHz, and most preferably below about two GHz. In addition, it is desirable to provide a linear distributed amplifier with substantial bandwidth, controlled terminal impedances and stability. Furthermore, additional desirable features will become apparent to one skilled in the art from the drawings, foregoing background of the invention and following detailed description of a preferred exemplary embodiment, and appended claims.

### BRIEF DESCRIPTION OF THE DRAWINGS

The present invention will hereinafter be described in conjunction with the appended drawing figures, wherein like numerals denote like elements, and:

FIG. 1 is a schematic circuit diagram of a distributed amplifier according to the prior art;

FIG. 2 is a schematic circuit diagram of a distributed amplifier having multiple amplifier cells with multiple transistors in a cascode configuration and negative feedback according to a preferred exemplary embodiment of the present invention;

FIG. 3 is one of the multiple amplifier cells of FIG. 2 in greater detail according to a preferred exemplary embodiment of the present invention;

FIG. 4 is a multi-layer ceramic package of the amplifier cell of FIG. 3 according to a preferred exemplary embodiment of the present invention; and

FIG. 5 is an inductor embedded within multiple ceramic layers of the multi-layer ceramic package of FIG. 4 according to a preferred exemplary embodiment of the present invention.

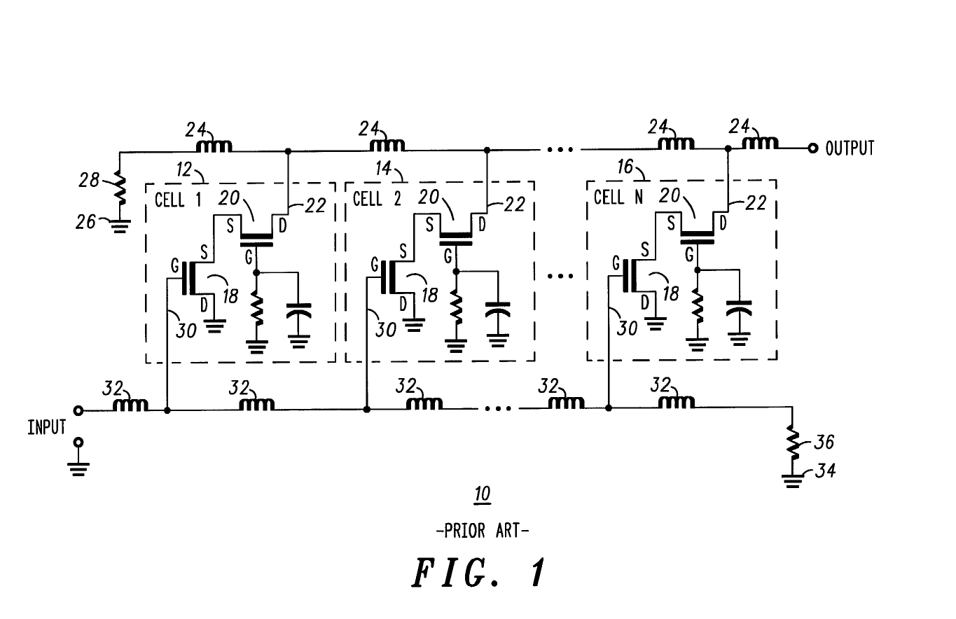

### DETAILED DESCRIPTION OF A PREFERRED EXEMPLARY EMBODIMENT

The following detailed description of a preferred embodiment is merely exemplary in nature and is not intended to limit the invention or the application and uses of the invention.

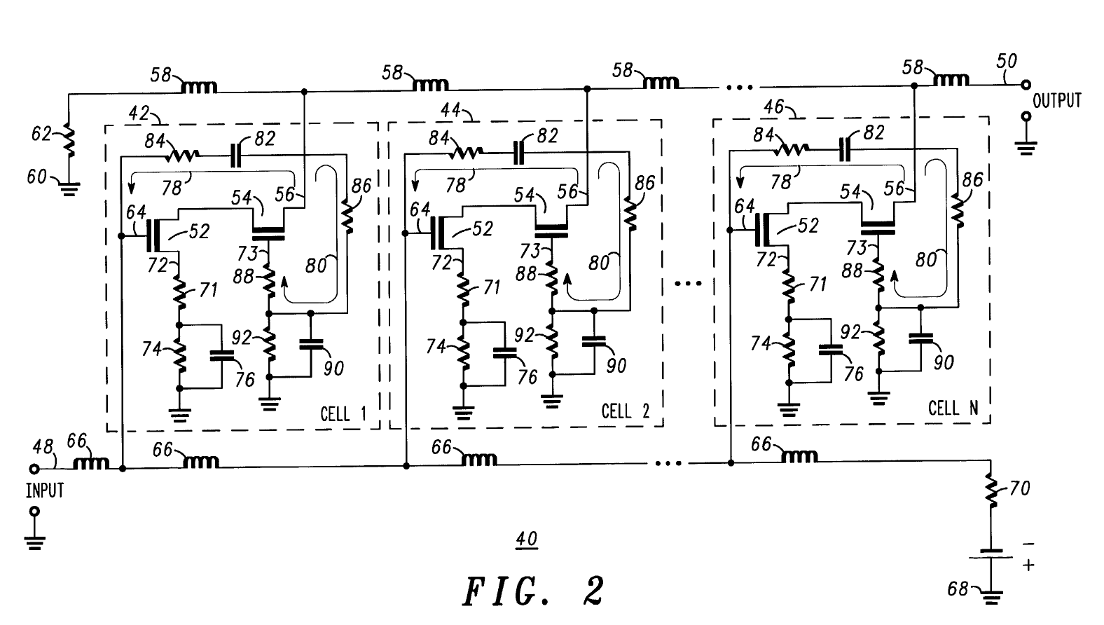

Referring to FIG. 2, a distributed amplifier 40 is illustrated according to a preferred exemplary embodiment of the present invention. The distributed amplifier 40 of the preferred exemplary embodiment has N amplifier cells (42,44,46) connected to the input transmission line 48 and the output transmission line 50. Preferably, N is greater than two, more preferably greater than three, and most preferably greater than or equal to three and less than or equal to six. The N amplifier cells (42,44,46) include a first transistor 52 in a cascode configuration with a second transistor 54. The first transistor 52 and/or the second transistor 54 are preferably a Field Effect Transistor (FET), more preferably a High Electron Mobility Transistor (HEMT) and most preferably Pseudomorphic High Electron Mobility Transistor (PHEMT) However, any number of transistors can be used for the first transistor 52 and/or the second transistor 54 in accordance with the present invention, such as a bipolar junction transistor (BJT).

The cascode configuration of the first transistor 52 and second transistor 54 of the N cells (12,14,16) has the first transistor 52 in a common source arrangement and the first transistor 52 is configured to drive the second transistor 54. The second transistor 54 of the N cells (42,44,46) is connected in a common gate arrangement and the first transistor 52 of the N cells (42,44,46) is connected in a common source arrangement. The drain terminal 56 of the second transistor 52 of the N cells (42,44,46) is coupled with output-line inductances 58, which are connected to an output-line ground 60 with an output-line termination resistance 62. The gate terminal 64 of the first transistor 52 of the N cells (42,44,46) is coupled with input-line inductances 66 that are connected to an input-line ground 68 with an input-line termination resistance 70. The source terminal 72 of the first transistor 52 of the N cells (42,44,46) is biased with a first biasing resistor (Rₑ₁) 71 in series with a second biasing resistor (R_{B1}) 74 in parallel with a first biasing capacitor (C_{B1}) 76. The drain terminal 56 of the second transistor 54 of the N cells (42,44,46) and the gate terminal 64 of the first transistor 52 of the N cells (42,44,46) is configured with a first feedback loop 78 and the drain terminal 56 and the gate terminal 73 of the second transistor 54 of the N cells (42,44,46) is configured with a second feedback loop 80.

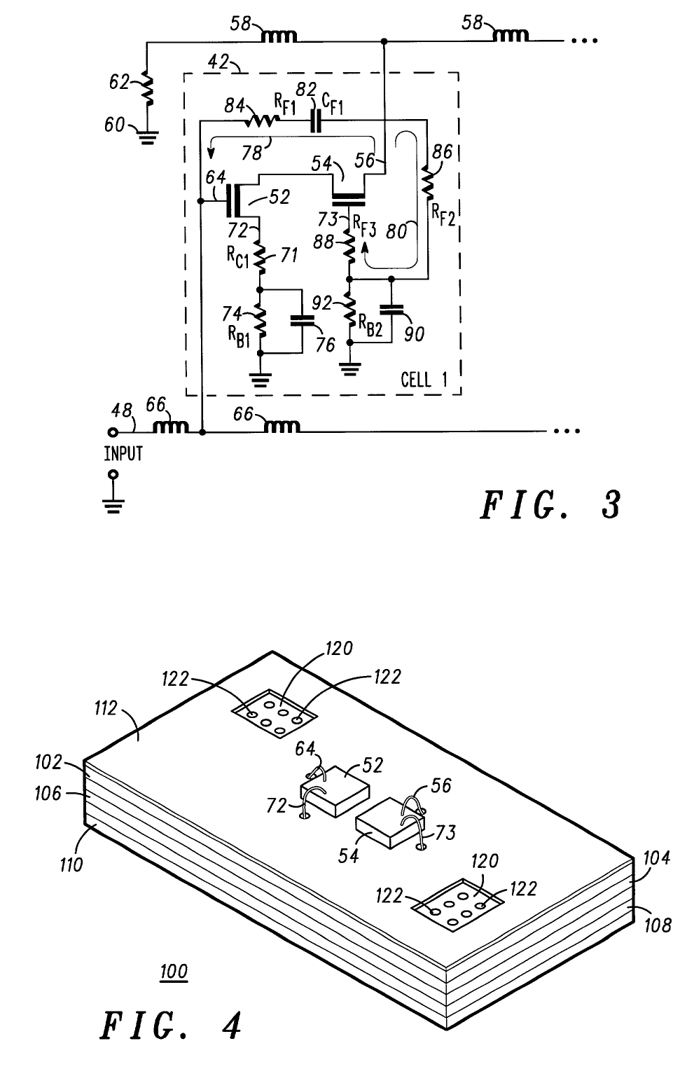

More specifically and referring to FIG. 3, which provides an enlarged view of the first cell 42 of the distributed amplifier 40, the first transistor 52 is configured with the first feedback loop 78, which is preferably a shunt feedback loop, and the second transistor 54 is configured with the second feedback loop 80, which is also preferably a shunt feedback loop. The shunt feedback loop configuration forming the first feedback loop 78 is provided with a first feedback capacitor (C_{F1}) 82 in series with a first feedback resistor (R_{F1}) 84. The shunt feedback loop configuration forming the second feedback loop 80 is provided with a second feedback resistor (R_{F2}) 86 in series with a third feedback resistor (R_{F3}) 88, which are connected to a second biasing capacitor (C_{B2}) 90 in parallel with a second biasing resistor (R_{B2}) 86. However, any number of feedback loops configurations can be used for the first feedback loop 72 and/or the second feedback loop 80 in accordance with the present invention.

The gain of the first cell 42 (G_{cell}), and the N cells of the distributed amplifier, configured with the negative feedback described in this detailed description of a preferred exemplary embodiment is based predominantly upon the ratio of the first feedback resistor (R_{F1}) 84 and the first series feedback resistor (Rₑ₁) 71. More specifically, the gain of the first cell 42 (G_{cell}), and the N cells of the distributed amplifier, configured with the negative feedback described in this detailed description of a preferred exemplary embodiment can be expressed as follows:

G_{cell}≈R_{F1}/Rₑ₁ (1)

As can be appreciated by one of ordinary skill in the art, the gain of the first cell 42 (G_{cell}), and the N cells of the distributed amplifier, configured with the negative feedback described in this detailed description of a preferred exemplary embodiment is not a function of temperature, termination bias or DC bias. Furthermore, the terminal impedances of the cell (i.e., the input impedance (Zᵢₙ) and output impedance (Zₒᵤₜ) of the first cell 42, and the N cells of the distributed amplifier), configured with the negative feedback described in this detailed description of a preferred exemplary embodiment is controllable as the terminal impedances are predominantly based upon the first feedback resistor (R_{F1}) 84 and the first series feedback resistor (Rₑ₁) 71. More specifically, the input impedance (Zᵢₙ) and the output impedance (Zₒᵤₜ) of the first cell 42, and the N cells of the distributed amplifier, configured with the negative feedback described in this detailed description of a preferred exemplary embodiment can be expressed as follows:

Zᵢₙ≈(R_{F1}*Rₑ₁)/Zₒᵤₜ (2)

Zₒᵤₜ≈(R_{F1}*Rₑ₁)/Zᵢₙ (3)

Furthermore, distortion is improved by approximately the following:

Distortion=10 log [(gₘ*Rₒᵤₜ)/(R_{F1}/Rₑ₁)] (4)

Where gₘ is the transconductance of the first transistor 52 and the second transistor 54 and Rₒᵤₜ is the output load of the distributed amplifier 40.

The first cell 42 and the N cells of the distributed amplifier that are configured with the negative feedback described in this detailed description of a preferred exemplary embodiment can be designed for any number of frequencies and gains with the selection of particular circuit element values. More specifically, the low frequency cutoff (F_{LC}) of the first cell 42 and the N cells of the distributed amplifier that are configured with the negative feedback described in this detailed description of a preferred exemplary embodiment can be selected according to the following relationship:

F_{LC}≈1/(R_{B1}*C_{B1}) (5)

The feedback loop cutoff frequency (f_{c(feedback loop)}) can be selected according to the following relationship:

f_{c(feedback loop)}≈1/(R_{F1}*C_{F1}) (6)

The bias voltage (V_{b2}) for the second transistor 54 can be selected according to the following relationship:

V_{b2}≈[V_{cc}(R_{B2}/(R_{B2}+R_{F2}))] (7)

The bias voltage (V_{b1}) of the first transistor 52 can be selected according to the following relationship:

V_{gs1}≈V_{b1}=I_{ds}(R_{b1}+Rₑ₁) (8)

The gain of the first cell 42 (G_{cell}) can be selected according to equation (1), and the third feedback resistor (R_{F3}) is selected for stability using any number of simulation techniques available for circuit analysis and evaluation.

The distributed amplifier of the present invention is preferably designed to operate at frequencies below about twenty GHz, more preferably below about ten GHz, even more preferably to operate at frequencies below about five GHz and most preferably to operate at frequencies below about two GHz. Therefore, the distributed amplifier of the present invention is preferably fabricated as a multi-layer ceramic device and more preferably as Low Temperature Co-fired Ceramic (LTCC), since the multi-layer ceramic structure enables the realization of circuit elements in a relatively small space, including vertically or horizontally wound high Q inductors. In addition, the multi-layer ceramic structure for the distributed amplifier minimizes interconnection parasitic reactance between active and passive circuit elements and provides thermal vias for removal of excess heat generated by the distributed amplifier.

Referring to FIG. 4, a multi-layer ceramic (MLC) structure 100 for the distributed amplifier cell 42 (i.e., a MLC distributed amplifier cell) of FIG. 3 is shown according to a preferred exemplary embodiment of the present invention. Preferably, the MLC structure 100 is a LTCC. The MLC structure 100 is comprised of multiple ceramic layers (102,104,106,108,110) connected to the first transistor 52 and second transistor 54 that are electrically connected in a cascode configuration. The first transistor 52 and second transistor 54 are preferably mounted to the surface 110 of the multiple ceramic layers (102,104,106,108,110) with any number of surface mounting techniques and electrically connected to electrical components formed within one or more of the ceramic layers (102,104,106,108,110) with multiple through-holes, which are referred to herein as vias, in one or more of the ceramic layers (102,104,106,108,110). In addition, the MLC structure 100 is preferably formed with a cavity 120 with at least one and more preferably multiple thermal vias 122 that are configured to remove excess thermal energy generated by the electrical components embedded in the multiple ceramic layers (102,104,106,108,110).

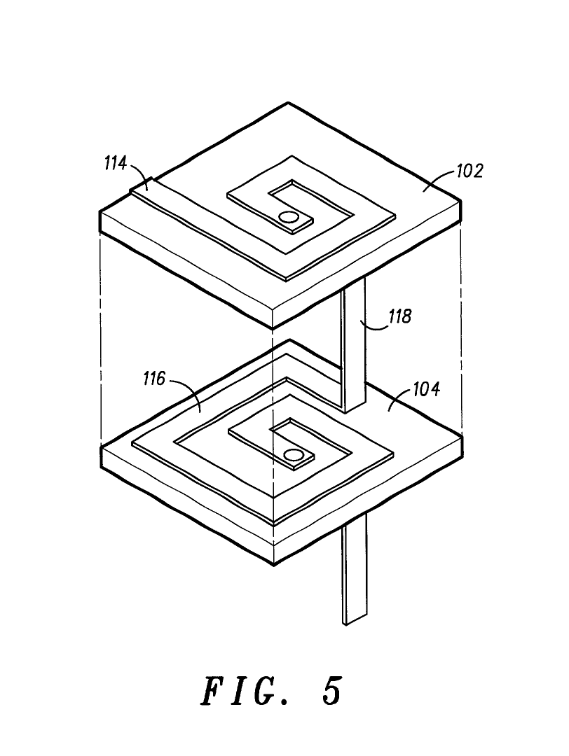

According to a preferred exemplary embodiment of the present invention, the first transistor 52 is connected to the input transmission line having the input line inductor embedded within the first ceramic layer 102 and the second ceramic layer 104 as shown in FIG. 5. Referring to FIG. 5, the first portion 114 of the input line inductor is connected to the second portion 116 of the input line inductor with an input line via 118. The dimensions of the traces within the first ceramic layer 102 and the second ceramic layer 104 provides the value of the input line inductor. As can be appreciated, this provides a vertically wound inductor with a high Q in a relatively small space.

The second transistor 54 is connected to the input transmission line having the input line inductor embedded within one or more of the ceramic layers (102,104,106,108,110) as discussed with reference to FIG. 5. In addition, the biasing capacitors (C_{B1},C_{B2}) and the feedback capacitor (C_{F1}) are preferably formed in a manner that is similar to the input line inductor and the output line inductor by locating a first parallel plate in one of the ceramic layers and a second parallel plate in one of the other ceramic layers adjacent to the first parallel plate, which are separated by another one of the ceramic layers. For example, the first parallel plate of a capacitor can be embedded in the second ceramic layer 104 adjacent to the second parallel plate embedded in the fourth ceramic layer 108 and separated by the third ceramic layer 106. The dielectric constant of the ceramic layers and the dimensions of the parallel plates can be adjusted to provide the value of the capacitor. Furthermore, any number of strip line components or microstrip components can be embedded into one or more of the ceramic layers to form the amplifier cell 42 illustrated in FIG. 3 and the distributed amplifier 40 shown in FIG. 2, including, but not limited to resistors.

As can be appreciated by one of ordinary skill in the art, the amplifier cell 42 of FIG. 3 and the distributed amplifier 40 of FIG. 2 that is configured with the electrical components embedded in the multiple ceramic layers (102,104,106,108,110) of the MLC structure 100 as previously described with reference to FIGS. 4 and 5 provides a distributed amplifier that is designed for frequencies below about twenty GHz, more preferably below about ten GHz, even more preferably below 5 GHz and most preferably below 2 GHz in a cost effect manner. Furthermore, the MLC structure 100 of FIGS. 4 and 5 provides a configuration for the removal of excess thermal energy with thermal vias in one or more of the ceramic layers (102,104,106,108). In addition, interconnection parasitic reactance between active and passive components is minimized with the MLC structure 100 of FIGS. 4 and 5.

From the foregoing description, it should be appreciated that a distributed amplifier is provided that presents significant benefits that have been presented in the background of the invention and detailed description of a preferred exemplary embodiment and also presents significant benefits that would be apparent to one skilled in the art. Furthermore, while a preferred exemplary embodiment has been presented in the foregoing description of a preferred exemplary embodiment, it should be appreciated that a vast number of variations in the embodiments exist. Lastly, it should be appreciated that these embodiments are preferred exemplary embodiments only, and are not intended to limit the scope, applicability, or configuration of the invention in any way. Rather, the foregoing detailed description provides those skilled in the art with a convenient road map for implementing a preferred exemplary embodiment of the invention. It being understood that various changes may be made in the function and arrangement of elements described in the exemplary preferred embodiment without departing from the spirit and scope of the invention as set forth in the appended claims.

What is claimed is:

1. A distributed amplifier, comprising:
an input transmission line;
an output transmission line;
a first distributed amplifier cell connected to said input transmission line and said output transmission line, said first distributed amplifier cell having a first transistor and a second transistor in a first cascode configuration between said input transmission line and said output transmission line, said first transistor is configured with a first feedback loop and said second transistor is configured with a second feedback loop; and
a second distributed amplifier cell connected to said input transmission line and said output transmission line, said second distributed amplifier cell having a third transistor and a fourth transistor in a second cascode configuration between said input transmission line and said output transmission line, said third transistor is configured with a third feedback loop and said fourth transistor is configured with a fourth feedback loop.

2. The distributed amplifier of claim 1, further comprising a third distributed amplifier cell connected to said input transmission line and said output transmission line, said third distributed amplifier cell having a fifth transistor and a sixth transistor in a third cascode configuration between said input transmission line and said output transmission line, said fifth transistor is configured with a fifth feedback loop and said sixth transistor is configured with a sixth feedback loop.

3. The distributed amplifier of claim 2, further comprising a fourth distributed amplifier cell connected to said input transmission line and said output transmission line, said fourth distributed amplifier cell having a seventh transistor and a eighth transistor in a fourth cascode configuration between said input transmission line and said output transmission line, said seventh transistor is configured with a seventh feedback loop and said eighth transistor is configured with an eighth feedback loop.

4. The distributed amplifier of claim 3, further comprising a fifth distributed amplifier cell connected to said input transmission line and said output transmission line, said fifth distributed amplifier cell having a ninth transistor and a tenth transistor in a fifth cascode configuration between said input transmission line and said output transmission line, said ninth transistor is configured with a ninth feedback loop and said tenth transistor is configured with an tenth feedback loop.

5. The distributed amplifier of claim 4, further comprising a sixth distributed amplifier cell connected to said input transmission line and said output transmission line, said sixth distributed amplifier cell having an eleventh transistor and a twelfth transistor in a sixth cascode configuration between said input transmission line and said output transmission line, said eleventh transistor is configured with a eleventh feedback loop and said twelfth transistor is configured with an twelfth feedback loop.

6. The distributed amplifier of claim 1, wherein said first transistor and said second transistor is a field effect transistor (FET).

7. The distributed amplifier of claim 1, wherein said first transistor is a pseudomorphic high electron mobility transistor (PHEMT).

8. The distributed amplifier of claim 1, wherein said first feedback loop comprises a first feedback resistor connected in series with a first feedback capacitor.

9. The distributed amplifier of claim 1, wherein said second feedback loop comprises a second feedback resistor in series with a third feedback resistor.

10. A distributed amplifier, comprising:
an input transmission line;
an output transmission line; and
N amplifier cells connected to said input transmission line and said output transmission line, each of said N amplifier cells comprising:
a first transistor connected to said input transmission line;
a second transistor connected to said first transistor in a cascode configuration and connected to said output transmission line;
a first feedback loop connected to said first transistor; and
a second feedback loop connected to said second transistor.

11. The distributed amplifier of claim 9, wherein N is an integer that is greater than one.

12. The distributed amplifier of claim 9, wherein N is an integer that is greater than two.

13. The distributed amplifier of claim 9, wherein N is an integer that is less than six.

14. A distributed amplifier section, comprising:
an input transmission line;
an output transmission line; and
N amplifier cells connected to said input transmission line and said output transmission line, each of said N amplifier cells comprising:
a first field effect transistor connected between said first transmission line and said output transmission line, said first field effect transistor having a first gate terminal, a first source terminal and a first drain terminal, said first gate terminal connected to said first transmission line;
a second field effect transistor cascoded with said first field effect transistor between said first transmission line and said output transmission line, said second field effect transistor having a second gate terminal, a second source terminal and a second drain terminal, said second source terminal connected to said first drain terminal and said second drain terminal connected to said output transmission line;
a first feedback loop formed between said second drain terminal and said first gate terminal; and
a second feedback loop formed between said second gate terminal and said second drain terminal.

15. The distributed amplifier of claim 9, wherein N is an integer that is greater than one.

16. The distributed amplifier of claim 9, wherein N is an integer that is greater than two.

17. The distributed amplifier of claim 9, wherein N is an integer that is less than six.

18. A Multi-Layer Ceramic (MLC) distributed amplifier cell, comprising:
a first transistor;
a second transistor connected to the first transistor in a cascode configuration;
a plurality of ceramic layers connected to the first transistor and the second transistor, said plurality of ceramic layers comprising a plurality of electrical components formed as an integral part of one or more of said plurality of ceramic layers, wherein one or more of said plurality of electrical components are configured to provide a first feedback loop for said first transistor and a second feedback loop for said second transistor.

18. The MLC distributed amplifier cell of claim 18, wherein said plurality of ceramic layers is a plurality of Low Temperature Co-fired Ceramic layers (LTCC).

19. The MLC distributed amplifier cell of claim 18, wherein the MLC distributed amplifier cell is one of N MLC distributed amplifiers cells configured to operate at frequencies below about twenty GHz.

20. The MLC distributed amplifier cell of claim 18, wherein the MLC distributed amplifier cell is one of N MLC distributed amplifiers cells configured to operate at frequencies below about ten GHz.

21. The MLC distributed amplifier cell of claim 18, wherein the MLC distributed amplifier cell is one of N MLC distributed amplifiers cells configured to operate at frequencies below about five GHz.

22. The MLC distributed amplifier cell of claim 18, wherein the MLC distributed amplifier cell is one of N MLC distributed amplifiers cells configured to operate at frequencies below about two GHz.

23. The MLC distributed amplifier cell of claim 18, further comprising a thermal via configured to remove thermal energy from at least one of said plurality of electrical components.
